(19) United States
(12) Patent Application Publication
(10) Pub. No.: US 2024/0242987 A1
(43) Pub. Date: Jul. 18, 2024

(54) WAFER TEMPERATURE MEASUREMENT FOR WET ETCHING BATH APPLICATIONS

(71) Applicant: Tokyo Electron Limited, Tokyo (JP)

(72) Inventors: Ivan MALEEV, Fremont, CA (US); Yaowu MA, Fremont, CA (US); Zheng YAN, Fremont, CA (US); Basanta BHADURI, Fremont, CA (US)

(73) Assignee: Tokyo Electron Limited, Tokyo (JP)

(21) Appl. No.: 18/620,541

(22) Filed: Mar. 28, 2024

Related U.S. Application Data
(63) Continuation-in-part of application No. 18/321,432, filed on May 22, 2023.
(60) Provisional application No. 63/347,713, filed on Jun. 1, 2022.

(51) Int. Cl. H01L 21/67; G01K 1/02; G01K 11/00

(52) U.S. Cl. CPC H01L 21/67248; G01K 1/026; G01K 11/00; H01L 21/67086

(57) ABSTRACT

Aspects of the disclosure provide a wet etch semiconductor-processing system, which can include a wet processing bath configured to be filled with a processing liquid and configured for one or more semiconductor samples to be placed vertically in parallel therein and immersed in the processing liquid, and a sensor optically coupled to one of the semiconductor samples. The sensor can be configured to form an illumination beam, collect bandgap photoluminescence (PL) light excited by the illumination beam onto a surface of the semiconductor sample at an illuminated spot, and measure spectral intensities of the bandgap PL light in a vicinity of a semiconductor bandgap wavelength of the semiconductor sample. The sensor can be arranged with respect to the wet processing bath such that the sensor directs the illumination beam onto the surface of the semiconductor sample at the illuminated spot and receives the bandgap PL light from the illuminated spot.

### CROSS-REFERENCE TO RELATED APPLICATIONS

This present application is a continuation-in-part (CIP) of U.S. application Ser. No. 18/321,432 filed on May 22, 2023, which claims the benefit of U.S. Provisional Application No. 63/347,713 filed on Jun. 1, 2022, which are incorporated herein by reference in their entirety.

### FIELD OF THE PRESENT DISCLOSURE

The present disclosure relates generally to temperature measurements, and, in particular, to optical sensors for remote wafer temperature measurements in semiconductor wafer manufacturing processes.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor wafer manufacturing processes may require a remote sensor to detect temperature of wafers inside a container or bath filled with processing liquid, where both the container walls and the processing liquid may not be transparent to mid-infrared wavelengths. This lack of transparency rules out the use of traditional radiation-based temperature sensors.

One example is a wet etching process where a batch of wafers are placed inside a quartz bath filled with a processing liquid containing phosphoric acid (H₃PO₄), water, and similar chemicals. Multiple quartz baths may be nested one within another, separated by processing liquid-filled regions. Wafer temperature sensing must occur along optical paths traversing the quartz walls, and across the processing liquid-filled regions, which processing liquid may contain bubbles. The bubbles present in the processing liquid may cause problems, e.g., signal fluctuation, due to movement within the liquid, for example. A statistical window filter may be employed to remove the signal fluctuations, noise and other anomalies. It may be critical for process control to accurately measure the wafer temperature inside the quartz bath, and preferably at multiple points across the wafer, so wet etching process uniformity can be inferred from the wafer temperature distribution.

If wafer temperatures range from 100 to 170° C., the corresponding peak of black-body radiation is in the 6 to 8 μm wavelength region, in the mid-infrared, while quartz transmits infrared (IR) radiation only below wavelengths of approximately 4 μm. IR transmission of water and H₃PO₄ are negligible above wavelengths of about 1.7 μm.

The need clearly exists for a sensor that can measure wafer temperature in such challenging optical access conditions, utilizing parts of the optical spectrum that are not affected by IR transmission loss, i.e., primarily in the near infrared (NIR).

### SUMMARY

Disclosed is a concept of a remote temperature sensor that allows measurement of temperature of wafers or other objects comprising silicon (Si) or other semiconductor materials placed inside containers or baths made of quartz or similar materials, and immersed in liquids opaque to mid-infrared. The disclosed method does not rely on thermal radiation from the wafer itself.

The concept is based on the physical effect of semiconductor band-to-band absorption measurements from photoluminescence (PL). The effect relies on the temperature dependence of the distribution of electrons in the semiconductor valence and conduction bands. At higher temperatures electrons generally occupy higher energy levels. Information about the electron distribution across energy levels may be obtained by illuminating a sample with photons of a known wavelength and analyzing an acquired spectrum of PL photons emitted by the illuminated sample. Sample temperature may be determined from characteristics of the PL spectrum, such as the spectral peak wavelength and the spectral intensity distribution.

In an embodiment, a near-infrared (NIR) light source with focusing optics creates an illuminated spot on the sample made of semiconductor material. Collection optics can be used to collect bandgap PL light emitted by the sample at the illuminated spot and transmit it to an optical detector such as a spectrometer or other suitable detector which allows spectral analysis in the bandgap wavelength region, typically around 1100 nm for silicon (Si). The spectral intensity distribution of bandgap PL light can be used to determine the sample temperature, using a suitable calibration.

Aspects of the present disclosure provide a wet etch semiconductor-processing system. For example, the wet etch semiconductor-processing system can include a wet processing bath configured to be filled with a processing liquid and configured for one or more semiconductor samples to be placed vertically in parallel therein and immersed in the processing liquid, and a first sensor configured to measure first temperature of a first semiconductor sample of the semiconductor samples. The first sensor can be configured to form a first illumination beam, collect first bandgap photoluminescence (PL) light excited by the first illumination beam onto a first surface of the first semiconductor sample at a first illuminated spot, and measure first spectral intensities of the first bandgap PL light in a vicinity of a first semiconductor bandgap wavelength of the first semiconductor sample. The first sensor can be arranged with respect to the wet processing bath such that the first sensor directs the first illumination beam onto the first surface of the first semiconductor sample at the first illuminated spot and receives the first bandgap PL light from the first illuminated spot.

In an embodiment, the wet processing bath can include a top wall that is transparent to a first wavelength of the first illumination beam, and the first sensor can be arranged to direct the first illumination beam through the top wall and the processing liquid onto the first surface of the first semiconductor sample at the first illuminated spot. In another embodiment, the wet processing bath can include a bottom wall that is transparent to a first wavelength of the first illumination beam, and the first sensor can be arranged to direct the first illumination beam through the bottom wall and the processing liquid onto the first surface of the first semiconductor sample at the first illuminated spot. In some embodiments, the processing liquid can include at least one of H₃PO₄, H₂O, H₂O₂, and H₂SO₄.

In an embodiment, the wet etch semiconductor-processing system can further include a second sensor configured to measure second temperature of a second semiconductor sample of the semiconductor samples. The second sensor can be configured to form a second illumination beam, collect second bandgap PL light excited by the second illumination beam on a second surface of the second semiconductor sample at a second illuminated spot, and measure second spectral intensities of the second bandgap PL light in a vicinity of a second semiconductor bandgap wavelength of the second semiconductor sample, and be arranged with respect to the wet processing bath such that the second sensor directs the second illumination beam onto the second surface of the second semiconductor sample at the second illuminated spot and receives the second bandgap PL light from the second illuminated spot. In another embodiment, the second semiconductor sample and the first semiconductor sample can be identical. In some embodiments, the second surface and the first surface can be identical.

In an embodiment, the first sensor can includes a light source configured to form the first illumination beam, focusing optics configured to direct the first illumination beam from the light source onto the first surface of the first semiconductor sample at the first illuminated spot, collection optics configured to collect the first bandgap PL light excited from the first semiconductor sample, at least one optical detector configured to measure first spectral intensities of the first bandgap PL light in the vicinity of a first semiconductor bandgap wavelength of the first semiconductor sample, and dichroic optics configured to transmit the first bandgap PL light from the collection optics to the at least one optical detector. For example, the dichroic optics can include a notch filter configured to suppress transmission of light at a first wavelength of the first illumination beam. As another example, the dichroic optics can include at least one of a dichroic mirror, a beam splitter, and an optical fiber. In an embodiment, the focusing optics and the collection optics can utilize a same lens for focusing the first illumination beam onto the first semiconductor sample and for collecting the first bandgap PL light from the first semiconductor sample, respectively. In another embodiment, the light source can include a near-infrared (NIR) laser diode or a light emitting diode (LED). For example, the first illumination beam can have wavelength of 785 nm. In an embodiment, the at least one optical detector can include a prism or grating spectrometer.

Aspects of the present disclosure further provide another wet etch semiconductor-processing system. For example, the another wet etch semiconductor-processing system can include a wet processing bath configured to be filled with a processing liquid and configured for one or more semiconductor samples to be placed vertically in parallel therein and immersed in the processing liquid, a sensor configured to measure temperature of a semiconductor sample of the semiconductor samples using bandgap PL effect, the sensor configured to form an illumination beam, collect bandgap photoluminescence (PL) light excited by the illumination beam onto a surface of the semiconductor sample at an illuminated spot, and measure spectral intensities of the bandgap PL light in a vicinity of a semiconductor bandgap wavelength of the semiconductor sample, and an optical fiber having a first end optically coupled to the sensor and a second end optically coupled to an optical pick-up head, wherein the pick-up head directs and focuses the illumination beam on the semiconductor sample, and then collects the bandgap PL light from the semiconductor sample. The optical fiber can be arranged with respect to the sensor and the wet processing bath such that the illumination beam from the sensor is focused into the first end of the optical fiber, transmitted by the optical fiber, and directed from the second end onto the surface of the semiconductor sample at the illuminated spot via the optical pick-up head, and the bandgap PL light is collected and transmitted by the optical fiber or a separate collection fiber to the sensor.

In an embodiment, the wet processing bath can include one or more slots for the one or more semiconductor samples to be placed vertically therein and a guide member formed between neighboring two of the slots, and the optical fiber can be embedded in the guide member. In another embodiment, the wet etch semiconductor-processing system can further include a guide lens optically coupled to the second end of the optical fiber, the guide lens configured to focus the illumination beam onto the surface of the semiconductor sample at the illuminated spot. In some embodiments, the guide member can include one or more guide teeth, and the guide lens can be located at a guide tooth of the guide teeth so that the illumination beam is focused on the surface of the semiconductor sample at the illuminated spot. For example, the guide tooth can have a side surface that is modified to a curved minor that acts as the guide lens. As another example, the guide tooth can have a top surface that is modified to a spherical/aspherical lens that acts as the guide lens.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a schematic diagram of an exemplary wet etch semiconductor-processing system in accordance with some embodiments of the present disclosure;

FIG. 1A shows spectral distributions of bandgap photoluminescence (PL) light for a silicon wafer that undergoes a shift of spectral peak with temperature;

FIG. 2A is a schematic diagram of an exemplary wet etch semiconductor-processing system in accordance with some embodiments of the present disclosure;

FIG. 2B is a schematic diagram of an exemplary wet etch semiconductor-processing system in accordance with some embodiments of the present disclosure;

FIG. 3 is a schematic diagram of an exemplary wet etch semiconductor-processing system in accordance with some embodiments of the present disclosure;

FIG. 4 is a schematic diagram of an exemplary sensor assembly in accordance with some embodiments of the present disclosure;

FIG. 5 is a schematic diagram of an exemplary guide lens of the sensor assembly in accordance with some embodiments of the present disclosure;

FIG. 6 is a schematic diagram of an exemplary wet etch semiconductor-processing system in accordance with some embodiments of the present disclosure;

FIG. 7 is a schematic diagram illustrating the sensor assembly embedded in a wet processing bath in accordance with some embodiments of the present disclosure;

FIG. 8 is a schematic diagram illustrating the sensor assembly embedded in the wet processing bath in accordance with some embodiments of the present disclosure;

FIG. 9 is a schematic diagram of an exemplary guide lens of the sensor assembly in accordance with some embodiments of the present disclosure; and

FIG. 10 is a schematic diagram of an exemplary guide lens of the sensor assembly in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

The following description is provided in the context of the use of a remote temperature sensor for measurement of the temperature of a semiconductor sample, e.g., a semiconductor wafer, placed inside a wet semiconductor-processing bath. It will be understood that the same method, apparatus, and system therefor are applicable to other remote temperature measurements of objects that exhibit bandgap photoluminescence (PL), in a variety of environments.

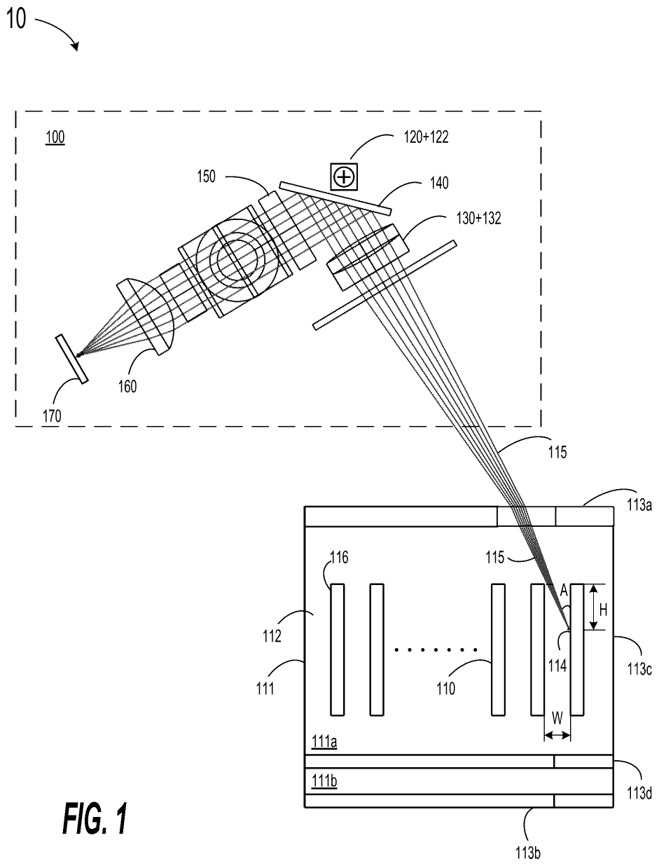

FIG. 1 is a schematic diagram of an exemplary remote temperature measurement sensor for a wet etch semiconductor-processing system 10 in accordance with some embodiments of the present disclosure. The wet etch semiconductor-processing system 10 can include a sensor 100, e.g., a temperature sensor, that is used to remotely detect the temperature of one or more objects 110, e.g., a semiconductor sample such as a semiconductor wafer, e.g., a silicon (Si) wafer, in a wet semiconductor manufacturing process. In an embodiment, a film, for example SiN hard mask or silicon oxide or a resist layer, may be formed on the wafer 110.

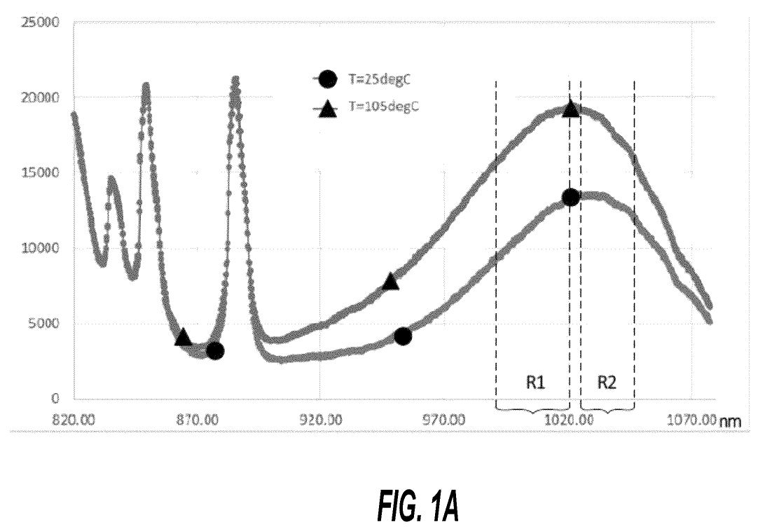

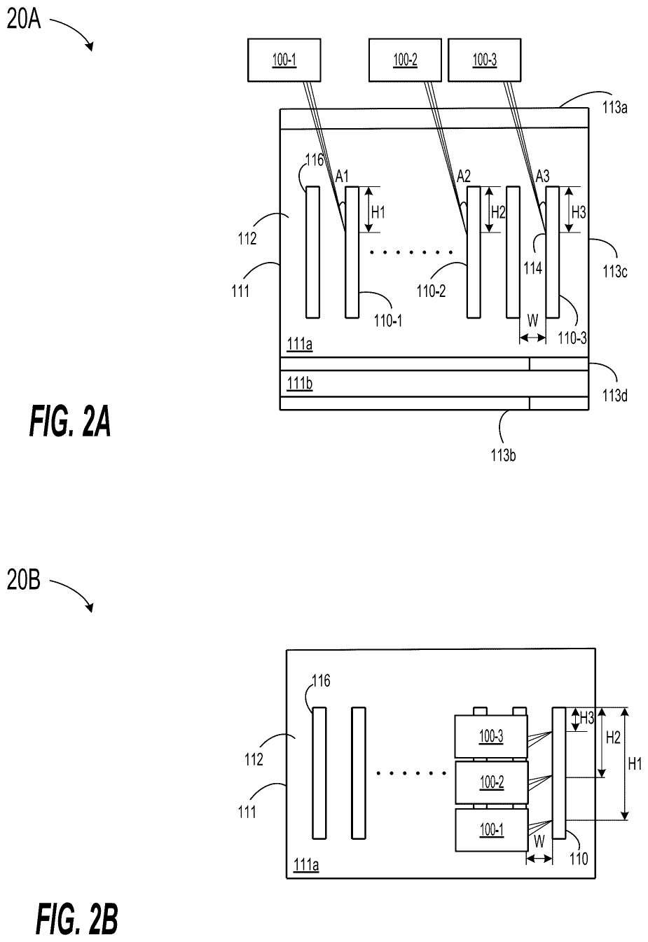

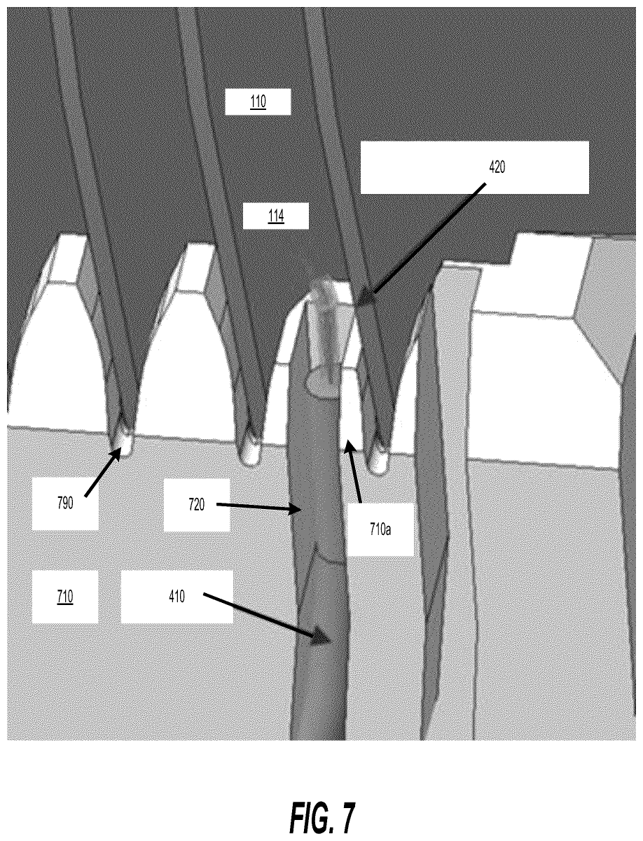

In the wet etch semiconductor-manufacturing process, the wafers 110 can be (e.g., vertically) located inside a wet processing bath (or a wet semiconductor-processing bath or container) 111, e.g., a wet etching bath, that is filled with a processing liquid 112 and includes a plurality of slots 790 (shown in FIG. 7) parallel to each other for the wafers 110 to be placed vertically therein and immersed in the processing liquid 112. For example, the wafers 110 can be parallel to each other and to a lateral wall 113c of the wet processing bath 111 (see e.g. FIG. 2A) and spaced at an interval W, e.g., 4.2 mm, from each other. In an embodiment, the wet processing bath 111 may include multiple containers (e.g., made of quartz) that are nested one within another and separated by regions that are filled with the processing liquid 112. In another embodiment, the wet processing bath 111 can include an inner (or top) bath 111a where the slots are formed and the wafers 110 are placed and an outer (or bottom) bath 111b that is located below the inner bath 111a and separated from the inner bath 111a by a partitioning member 113d, as shown in FIG. 1. In some embodiments, all of the processing liquid 112, and the partitioning member 113d, a top wall (or a cover) 113a, a bottom wall 113b and the lateral wall 113c (e.g., made of quartz) of the wet processing bath 111 (or of the multiple containers) may not be transparent to mid-infrared wavelengths. In an embodiment, the processing liquid 112 may contain at least one of water, H₂O₂, H₂SO₄, phosphoric acid (H₃PO₄), and similar chemicals.

In an embodiment, shown e.g., in FIG. 1, the sensor 100 can be arranged with respect to the wet processing bath 111 such that the sensor 100 sends illumination beam into and can collect from an illuminated spot 114 of a wafer surface (e.g., a working surface or a backside surface) 116 of one of the wafers 110 (e.g., at a distance H, e.g., 7 mm, from the edge of the wafer 110, or at a tilt angle A, e.g., 31°, with respect to the wafer surface 116) bandgap photoluminescent (PL) light (or PL light) 115 that is excited by an illumination beam and corresponds to the temperature of the illuminated spot 114 of the wafer 110. For example, the sensor 100 can be installed on the top wall 113a of the wet processing bath 111, as shown in FIG. 1. Illumination and collection beams can share same optics, as shown in FIG. 1, or they can have separate dedicated optical paths.

Optionally, the sensor 100 can include a light source 120 that is used to form the illumination beam. In an embodiment, the light source 120 can be a near infrared (NIR) light source, such as a laser diode or a light emitting diode (LED) operating at a wavelength of 785 nm, for example, and can form the illumination beam that is NIR light. Other light source wavelengths may be used, e.g., visible light, and alternative embodiments may include a narrowband LED or a broadband light source with an interference filter to select the wavelength range for wafer illumination.

Optionally, the sensor 100 can further include an illumination collimator 122. In an embodiment, the illumination collimator 122 can be built in the light source 120, as shown in FIG. 1. In another embodiment, the illumination collimator 122 can be separated from the light source 120. The illumination collimator 122 can be used to collimate the illumination beam formed by the light source 120.

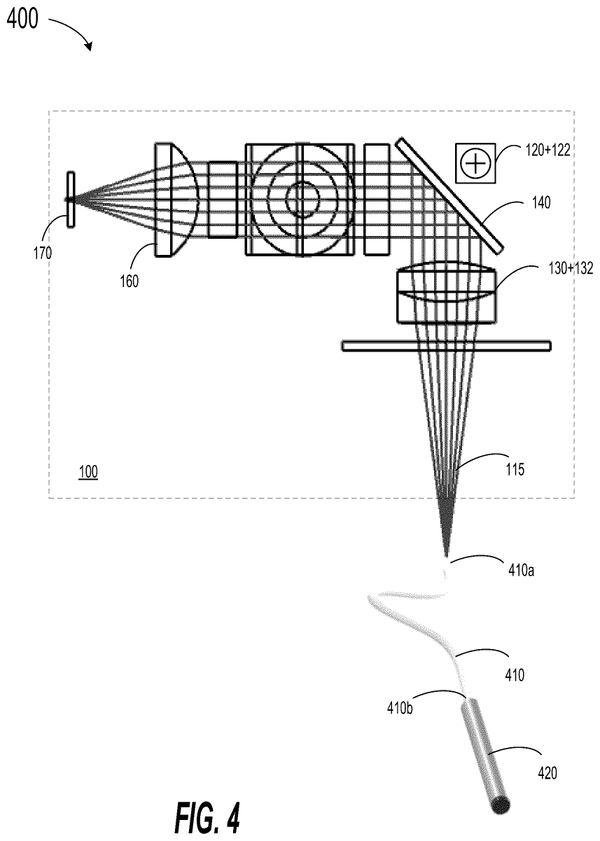

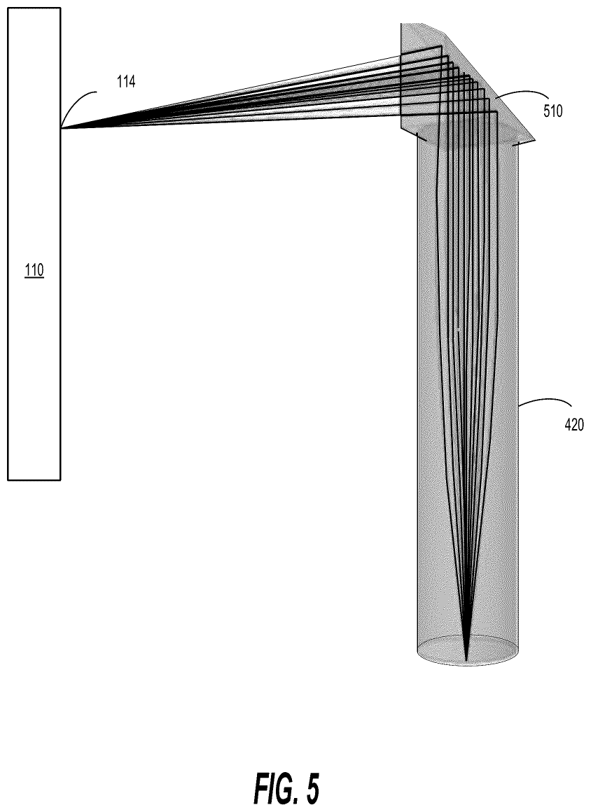

In an embodiment, the sensor 100 can further include focusing optics 130. The focusing optics 130 can be used to direct the collimated illumination beam onto the wafer surface 116 of the wafer 110 to form the illuminated spot 114 thereon. Before reaching the illuminated spot 114, the collimated illumination beam may traverse multiple quartz wall(s) (e.g., the top wall 113a) and multiple regions filled with the processing liquid 112. The illumination beam directed onto the wafer surface 116 (i.e., at the illuminated spot 114), optionally through the film formed on the wafer 110, can excite the wafer 110 to emit photon flux, in this case called the bandgap PL light (or PL light) 115. In one aspect, penetration of the illumination beam through the film formed on the wafer 110 enables temperature measurement of the underlying wafer 110 without regard to the film. In some embodiments, the sensor 100 can further include an optical fiber 410 (see FIG. 4) configured to transmit the illumination beam from the sensor 100 to a fiber sensor head 420 (see FIG. 5) and then to a desired location on the wafer 110. Same or different fiber may be used to collect PL light from the same location on the wafer 110 and send the collected PL light back into the sensor 100.

In an embodiment, the sensor 100 can further include collection optics 132. In an embodiment, the collection optics 132 can be integrated with the focusing optics 130 and include the same focusing lens, as shown in FIG. 1. In another embodiment, the focusing optics 130 and collection optics 132 can be separated and not aligned along the same optical axis. The collection optics 132 are designed to collect the PL light 115 excited by the wafer 110 at the illuminated spot 114. In an embodiment, the PL light 115 generally has a Lambertian distribution, and the purpose of the collection optics 132 is to collect as much of the PL light 115 as possible, after traversing the quartz walls 113 and the processing liquid 112, and pass the collected PL light 115 to at least one optical detector 170 of the sensor 100 with minimal losses.

In an embodiment, the sensor 100 can further include detector focusing optics (transmission optics) 160. The detector focusing optics 160 can direct and transmit the PL light 115 from the collection optics 132 onto the optical detector 170. In the example embodiment shown in FIG. 1, a shortpass filter 140, e.g., dichroic mirror (DM), is used to separate the NIR light of the illumination beam from the PL light 115, e.g., by passing laser light but reflecting PL light as PL wavelength is much longer than excitation laser wavelength, and direct the PL light 115 towards the optical detector 170. In some embodiments, the detector focusing optics 160 can further include a beam splitter and an optical fiber. In an embodiment, because the illumination beam may be of so much higher intensity than the collected PL light 115, a notch filter 150 with “notch center” wavelength corresponding to the wavelength of the NIR light source 120, e.g., 785 nm, may be used to further remove any illumination beam scattered into the optical detector path.

The optical detector 170 can be used to acquire and analyze the spectrum (or spectral intensities) of the PL light 115 from which the temperature of the wafer 110 can be determined (at the location of the illuminated spot 114). In an embodiment, the optical detector 170 may be a prism or grating spectrometer with a CCD, CMOS, photodiode (PD) array, position-sensitive device (PSD), etc., detector.

In an embodiment, the signals generated by the optical detector 170 can be fed into processing electronics (not shown) for amplification, filtering, AD conversion, and further processing needed for determination of the temperature of the wafer 110. For example, the wet etch semiconductor-processing system 10 can further include a controller coupled to the optical detector 170 and configured to acquire PL spectral light intensities from the optical detector 170 and determine temperature of the wafer 110 from the acquired PL spectral light intensities.

FIG. 1A shows the spectral distributions (or spectral intensities or spectrum) of PL light from a wafer in wet etching chamber 111, e.g., the PL light 115, for silicon (Si), e.g., the silicon wafer 110, which undergoes a shift of spectral peak with temperature, e.g., 25° C. and 105° C. With dual photodiodes or similar sensors measuring the spectral intensities of PL light at wavelengths λ₁ & λ₂ that are in the vicinity of bandgap wavelength of 1100 nm of the PL light, it is possible to use the measured intensities along with a suitable calibration to determine the temperature of the silicon wafer 110. For example, as the ratio of the spectral intensities at two wavelengths changes with the temperature of the wafer 110, the ratio of the spectral intensities at the two wavelengths λ₁ & λ₂ may be correlated to the temperature. A simpler or more complex metric and calibration involving the measured spectral intensities may be utilized. In an embodiment, the two wavelengths λ₁ & λ₂ can be selected within one or more highly sensitive regions of the spectrum of the PL light, e.g., regions R1 and R2, where the ratio of the spectral intensities of the PL light 115 at the two wavelengths λ₁ & λ₂ and the difference between the spectral distributions of the PL light 115 measured at different temperatures are large. Use of ratio of spectral intensities at two wavelengths allows to cancel overall intensity fluctuations due to both light source and sensor instabilities, as well as due to changes in transmission of chamber walls and processing fluid inside.

For more accuracy, more than two spectral intensities may be measured and utilized in the calibration and temperature determination. In an embodiment, the term “vicinity” may indicate a distance at 1, 2, 3, . . . , 99, 100, . . . , 199 or 200 nm from the bandgap wavelength.

More than one of the sensors 100 can be arranged with respect to the wet processing bath 111 (e.g., installed on the top wall 113a) in order to detect the temperatures of more than one of the e wafers 110 and/or the temperatures of one of the wafer 110 at more than one of the illuminated spots 114. For example, as shown in FIG. 2A an exemplary wet etch semiconductor-processing system 20A can include three of the sensors 100 (denoted by 100-1, 100-2 and 100-3) that are arranged with respect to the wet processing bath 111 such that the sensors 100-1, 100-2 and 100-3 can receive PL light from three of the wafers 110 (denoted by 110-1, 110-2 and 110-3) placed inside the wet processing bath 111 at three distances H1, H2 and H3 from the edges of the wafers 110-1, 110-2 and 110-3, respectively, or at three tilt angles A1, A2 and A3, respectively, to detect the temperatures of the wafers 110-1, 110-2 and 110-3. In an embodiment, at least two of the distances H1, H2 and H3 (and/or the tilt angles A1, A2 and A3) are the same. In another embodiment, at least two of the distances H1, H2 and H3 (and/or the tilt angles A1, A2 and A3) are different from each other. The example embodiment shown in FIG. 2A illustrates that the sensors 100-1, 100-2 and 100-3 receive the PL light from the wafers 110-1, 110-2 and 110-3 on the same wafer surface, e.g., the working surface or the backside surface. In some embodiments, the sensors 100-1, 100-2 and 100-3 can receive the PL light from the wafers 110-1, 110-2 and 110-3 on different wafer surfaces. For example, the sensors 100-1 and 100-2 can receive the PL light from the working surfaces of the wafers 110-1 and 110-2, and the sensor 100-3 can receive the PL light from the backside surface of the wafer 100-3.

As another example, as shown in FIG. 2B an exemplary wet etch semiconductor-processing system 20B can include three of the sensors 100 (denoted by 100-1, 100-2 and 100-3) that are arranged with respect to the wet processing bath 111 such that the sensors 100-1, 100-2 and 100-3 can receive PL light from three illuminated spots of one of the wafers 110 placed inside the wet processing bath 111 at three distances H1, H2 and H3 from the edge of the wafer, respectively, to detect the temperatures of the three illuminated spots of the wafer 110. In an embodiment, at least two of the distances H1, H2 and H3 are the same. In another embodiment, at least two of the distances H1, H2 and H3 are different from each other. The example embodiment shown in FIG. 2B illustrates that the sensors 100-1, 100-2 and 100-3 receive the PL light from the wafer 110 on the same wafer surface, e.g., the working surface or the backside surface. In some embodiments, the sensors 100-1, 100-2 and 100-3 can receive the PL light from the wafer 110 on different wafer surfaces. For example, the sensors 100-1 and 100-2 can receive the PL light from the working surface of the wafer 110, and the sensor 100-3 can receive the PL light from the backside surface of the wafer 110.

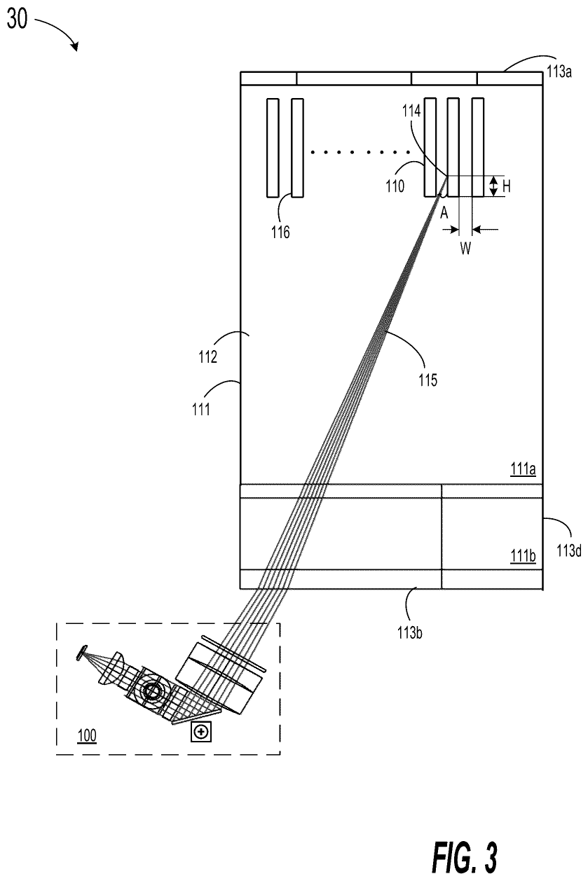

FIG. 3 is a schematic diagram of an exemplary wet etch semiconductor-processing system 30 in accordance with some embodiments of the present disclosure. The wet etch semiconductor-processing system 30 can include the wet processing bath 111 and one or more sensors, e.g., the sensor 100, that can be installed on the bottom wall 113b of the wet processing bath 111. In an embodiment, the sensor 100 can be arranged with respect to the wet processing bath 111 such that the sensor 100 can receive from an illuminated spot 114 of a wafer surface 116 of one of the wafers 110 (e.g., at a distance H, e.g., 7 mm, from the edge of the wafer 110, or at a tilt angle A, e.g., 31° , with respect to the wafer surface 116) PL light 115 that is excited by an illumination beam (not shown) generated by the light source 120 of the sensor 100 and corresponds to the temperature of the illuminated spot 114 of the wafer 110. More than one of the sensors 100 can be installed on the bottom wall 113b) in order to detect the temperatures of more than one of the wafers 110 and/or the temperatures of one of the wafers 110 at more than one of the illuminated spots 114.

In some embodiments, one or more sensors, e.g., the sensors 100 shown in FIGS. 1, 2A and 2B, can be installed on the top wall 113a of the wet processing bath 111, and another one or more sensors, e.g., the sensors 100 shown in FIG. 3, can be installed on the bottom wall 113b of the wet processing bath 111.

FIG. 4 is a schematic diagram of an exemplary sensor assembly 400 in accordance with some embodiments of the present disclosure. The sensor assembly 400 can include a sensor, e.g., the sensor 100, and an optical fiber 410 that is optically coupled to the sensor 100. Therefore, the excitation illumination beam generated by the light source 120 of the sensor 100 can be focused into one end (or a first end) 410a of the optical fibers 410 and the PL light 115 excited can be collected by the optical fiber 410 and transmitted to the sensor 100. Optionally, the sensor assembly 400 can further include a guide lens 420, e.g., a gradient-index (GRIN) lens, that is optically coupled to (e.g., integrated with) the other end (or a second end) 410b of the optical fiber 410. In an embodiment, the guide lens 420 can have a flat surface, which makes the guide lens 420 be easily aligned with the optical fiber 410. The guide lens 420 can be located within a space between two of the wafers 110 and configured to focus the excitation illumination beam from the optical fiber 410 onto the wafer surface 116 of the wafer 110 and collect and transmit the PL light 115 thus excited through the optical fiber 410 to the sensor 100. One end of the guide lens 420 that is not optically coupled to the optical fiber 410 can be a prism 510, as shown in FIG. 5. The prism 510 can turn the excitation illumination beam 90° toward the wafer 110.

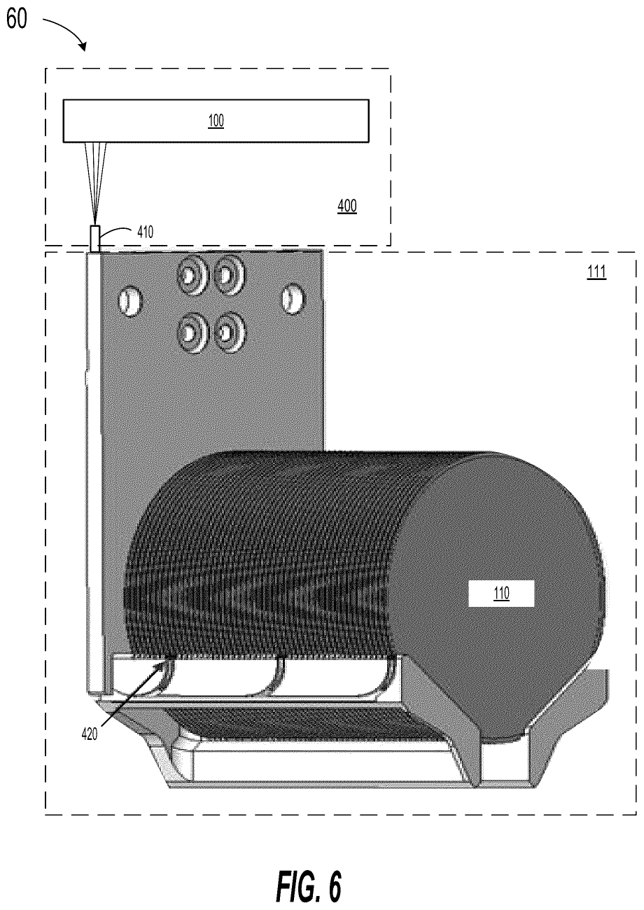

FIG. 6 is a schematic diagram of an exemplary wet etch semiconductor-processing system 60 in accordance with some embodiments of the present disclosure. The wet etch semiconductor-processing system 60 can include a wet processing bath (e.g., the wet processing bath 111) and one or more of sensor assemblies (e.g., the sensor assemblies 400). A plurality of wafers, e.g., the wafers 110, can be placed in the slots 790 (shown in FIG. 7) of the wet processing bath 111. The excitation illumination beam generated by the light source 120 of the sensor 100 of one of the sensor assemblies 400 can be focused into the first end 410a of the optical fiber 410 of the sensor assembly 400 and illuminated (e.g., through the guide lens 420 and the prism 510) on an illuminated spot (e.g., the illuminated spot 114) of a wafer surface (e.g., the wafer surface 116) of one of the wafers 110 from the second end 410b of the optical fiber 410. In an embodiment, the second end 410b of the optical fiber 410 can be optically coupled to an optical pick-up head, which can direct and focus the PL light on the wafer 110, and then collect the PL light from the wafer 110. The second end 410b of the optical fiber 410 can collect and transmit PL light, e.g., the PL light 115, thus excited by the wafer 110 at the illuminated spot 114 to the sensor 100.

In an embodiment, the optical fiber 410 and the guide lens 420 can be embedded in a guide member 710 (made of quartz, for example) of the wet processing bath 111 that is formed between neighboring two of the slots 790, as shown in FIG. 7. Therefore, the guide lens 420 can be located at one of the guide teeth 710a of the guide member 710 so that the excitation illumination beam can be focused on the wafer surface 116 of the wafer 110. In order to embed the optical fiber 410 and the guide lens 420, a machine, e.g., a computer numerical control (CNC) machine, can be used to mill a groove 720 at the bottom of the guide member 710, the optical fiber 410 and the guide lens 420 can then be bonded in the groove 720, and the same material as the guide member 710 (e.g., quartz) can be used to cover the groove 720. The guide teeth 710a of the guide member 710 have curvature, which will affect the focus quality of the guide lens 420. This curvature and the wavelengths of the excitation illumination beam and the PL light need to be considered when the guide lens 420 is designed.

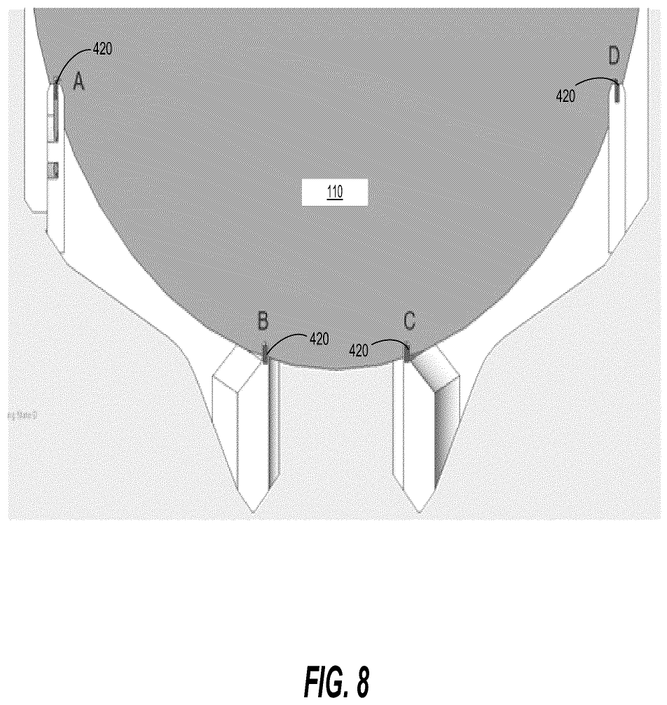

In an embodiment, the guide lens 420 can be mounted in front of each of the wafers 110, and the temperature distribution of the wet processing bath 111 can be measured from front to back. In another embodiment, the guide lens 420 can be mounted from left to right at locations A, B, C and D, as shown in FIG. 8, and the temperature distribution of the wet processing bath 111 can be measured from left to right and middle to bottom. The guide member 710 can protect the guide lens 420 and the optical fiber 410 from etching chemicals, e.g., the processing liquid 112, filled in the wet processing bath 111.

In an embodiment, the guide lens 420 can be rotated along a vertical axis so that the prism 510 is facing the drawing. There are two reasons for this rotation: 1) Manufacturers do not care the temperature at the edge of the wafer 110. They design the water flow of the wet processing bath 111 so that the temperature of the whole wafer surface 116 is uniform except the 5 mm edge area of the wafer 110. The rotation of the guide lens 420 along the vertical axis will make excitation illumination beam incident 5 mm away from the edge of the wafer 110. 2) Prevent reflected excitation illumination beam from going back to the guide lens 420. PL light generated from the illuminated spot 114 is the signal for temperature measurement. The intensity of the PL light is several orders of magnitude lower than the intensity of the excitation illumination beam. The reflected excitation illumination beam is background noise and should be blocked out completely.

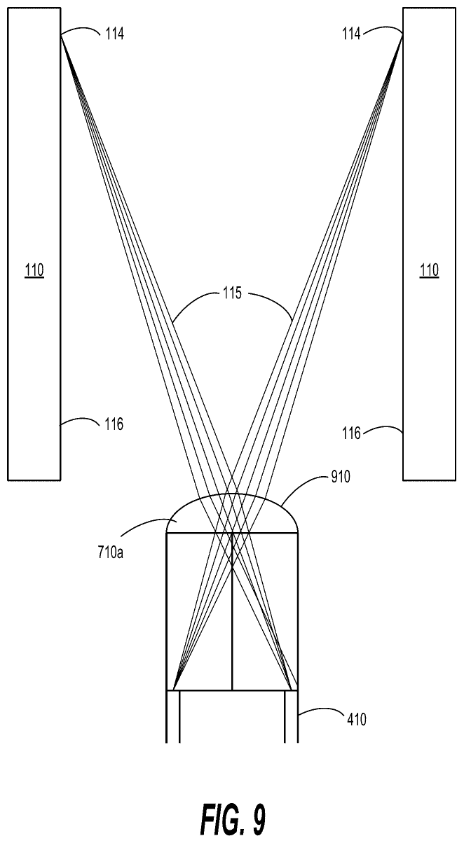

In an embodiment, the top surface of at least one of the guide teeth 710a can be modified to a spherical/aspherical lens 910, as shown in FIG. 9. Two of the optical fibers 410 can be inserted at the left and right sides of the quartz guide tooth 710a, respectively. The spherical/aspherical lens 910 will focus the excitation illumination beams to the wafer surfaces 116 (e.g., working surface and backside surface) of two of the wafers 110 at the illuminated spots 114. Changing the fiber angle can adjust the focal spot location, make sure the measured temperature is at interested position. The PL light 115 can be collected by the same path and eventually go back to the optical fibers 410 and then to the sensor 100. In some embodiments, only one of the optical fibers 410 can be inserted at the left or right side of the quartz guide tooth 710a.

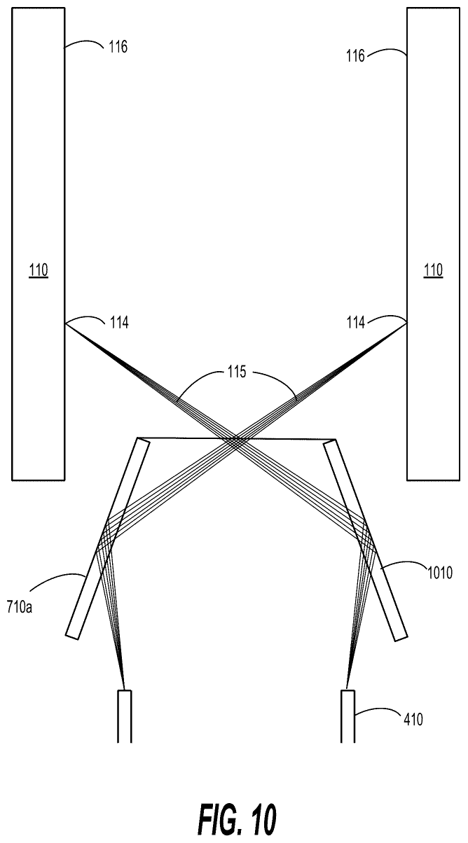

In another embodiment, the side surface of at least one of the guide teeth 710a can be modified to a curved minor 1010, as shown in FIG. 10. Two of the optical fibers 410 can be inserted perpendicular at the left and right edges of the quartz guide tooth 710a, respectively. A portion of the guide tooth 710a is exposed to the excitation illumination beam. The surface of the exposed portion is made of off-axis aspherical/spherical-cylindrical combination with reflective coating. The curved minor 1010 will focus the excitation illumination beam to the wafer surfaces 116 (e.g., working surface and backside surface) of two of the wafers 110. Changing the fiber angle can adjust the focal spot location, make sure the measured temperature is at interested position. The PL light 115 can be collected by the same path and eventually go back to the optical fibers 410 and then to the sensor 100. In some embodiments, only one of the optical fibers 410 can be inserted at the left or right edge of the quartz guide tooth 710a.

In various embodiment, other micro-optics lens, e.g., ball lens, which has very high efficiency for fiber coupling, can be integrated with the optical fiber 410 and the prism 510 for the application here. In order to improve measurement sensitivity, machine learning algorithms are developed to compensate the optical sensor's hysteresis, drift and trail offset.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A wet etch semiconductor-processing system, comprising:
a wet processing bath configured to be filled with a processing liquid and configured for one or more semiconductor samples to be placed vertically in parallel therein and immersed in the processing liquid; and
a first sensor configured to measure first temperature of a first semiconductor sample of the semiconductor samples, the first sensor configured to form a first illumination beam, collect first bandgap photoluminescence (PL) light excited by the first illumination beam onto a first surface of the first semiconductor sample at a first illuminated spot, and measure first spectral intensities of the first bandgap PL light in a vicinity of a first semiconductor bandgap wavelength of the first semiconductor sample,
wherein the first sensor is arranged with respect to the wet processing bath such that the first sensor directs the first illumination beam onto the first surface of the first semiconductor sample at the first illuminated spot and receives the first bandgap PL light from the first illuminated spot.

2. The wet etch semiconductor-processing system of claim 1, wherein the wet processing bath includes a top wall that is transparent to a first wavelength of the first illumination beam, and the first sensor is arranged to direct the first illumination beam through the top wall and the processing liquid onto the first surface of the first semiconductor sample at the first illuminated spot.

3. The wet etch semiconductor-processing system of claim 1, wherein the wet processing bath includes a bottom wall that is transparent to a first wavelength of the first illumination beam, and the first sensor is arranged to direct the first illumination beam through the bottom wall and the processing liquid onto the first surface of the first semiconductor sample at the first illuminated spot.

4. The wet etch semiconductor-processing system of claim 1, further comprising:
a second sensor configured to measure second temperature of a second semiconductor sample of the semiconductor samples, the second sensor configured to form a second illumination beam, collect second bandgap PL light excited by the second illumination beam on a second surface of the second semiconductor sample at a second illuminated spot, and measure second spectral intensities of the second bandgap PL light in a vicinity of a second semiconductor bandgap wavelength of the second semiconductor sample,
wherein the second sensor is arranged with respect to the wet processing bath such that the second sensor directs the second illumination beam onto the second surface of the second semiconductor sample at the second illuminated spot and receives the second bandgap PL light from the second illuminated spot.

5. The wet etch semiconductor-processing system of claim 4, wherein the second semiconductor sample and the first semiconductor sample are identical.

6. The wet etch semiconductor-processing system of claim 5, wherein the second surface and the first surface are identical.

7. The wet etch semiconductor-processing system of claim 1, wherein the first sensor includes:
a light source configured to form the first illumination beam;
focusing optics configured to direct the first illumination beam from the light source onto the first surface of the first semiconductor sample at the first illuminated spot;
collection optics configured to collect the first bandgap PL light excited from the first semiconductor sample;
at least one optical detector configured to measure first spectral intensities of the first bandgap PL light in the vicinity of a first semiconductor bandgap wavelength of the first semiconductor sample; and
transmission optics configured to transmit the first bandgap PL light from the collection optics to the at least one optical detector.

8. The wet etch semiconductor-processing system of claim 7, wherein the transmission optics include a notch filter configured to suppress transmission of light at a first wavelength of the first illumination beam.

9. The wet etch semiconductor-processing system of claim 7, wherein the transmission optics include at least one of a dichroic minor, a beam splitter, and an optical fiber.

10. The wet etch semiconductor-processing system of claim 7, wherein the focusing optics and the collection optics utilize a same lens for focusing the first illumination beam onto the first semiconductor sample and for collecting the first bandgap PL light from the first semiconductor sample, respectively.

11. The wet etch semiconductor-processing system of claim 7, wherein the light source includes a near-infrared (NIR) laser diode or a light emitting diode (LED).

12. The wet etch semiconductor-processing system of claim 11, wherein the first illumination beam has a wavelength of 785 nm.

13. The wet etch semiconductor-processing system of claim 7, wherein the at least one optical detector includes a prism or grating spectrometer.

14. The wet etch semiconductor-processing system of claim 1, wherein the processing liquid includes at least one of H₃PO₄, H₂O, H₂)₂, and H₂SO₄.

15. A wet etch semiconductor-processing system, comprising:
a wet processing bath configured to be filled with a processing liquid and configured for one or more semiconductor samples to be placed vertically in parallel therein and immersed in the processing liquid;
a sensor configured to measure temperature of a semiconductor sample of the semiconductor samples, the sensor configured to form an illumination beam, collect bandgap photoluminescence (PL) light excited by the illumination beam onto a surface of the semiconductor sample at an illuminated spot, and measure spectral intensities of the bandgap PL light in a vicinity of a semiconductor bandgap wavelength of the semiconductor sample; and
an optical fiber having a first end optically coupled to the sensor and a second end optically coupled to an optical pick-up head, wherein the pick-up head directs and focuses the illumination beam on the semiconductor sample, and then collects the bandgap PL light from the semiconductor sample,
wherein the optical fiber is arranged with respect to the sensor and the wet processing bath such that the illumination beam from the sensor is focused into the first end of the optical fiber, transmitted by the optical fiber, and directed from the second end onto the surface of the semiconductor sample at the illuminated spot via the optical pick-up head, and the bandgap PL light is collected and transmitted by the optical fiber to the sensor.

16. The wet etch semiconductor-processing system of claim 15, wherein the wet processing bath includes one or more slots for the one or more semiconductor samples to be placed vertically therein and a guide member formed between neighboring two of the slots, and the optical fiber is embedded in the guide member.

17. The wet etch semiconductor-processing system of claim 16, further comprising:
a guide lens optically coupled to the second end of the optical fiber, the guide lens configured to focus the illumination beam onto the surface of the semiconductor sample at the illuminated spot.

18. The wet etch semiconductor-processing system of claim 17, wherein the guide member includes one or more guide teeth, and the guide lens is located at a guide tooth of the guide teeth so that the illumination beam is focused on the surface of the semiconductor sample at the illuminated spot.

19. The wet etch semiconductor-processing system of claim 18, wherein the guide tooth has a side surface that is modified to a curved minor that acts as the guide lens.

20. The wet etch semiconductor-processing system of claim 18, wherein the guide tooth has a top surface that is modified to a spherical/aspherical lens that acts as the guide lens.
